(19) United States
(12) Patent Application Publication
(10) Pub. No.: US 2024/0188392 A1
(43) Pub. Date: Jun. 6, 2024

(54) Display Substrate, Display Apparatus, and Method for Preparing Display Substrate

(71) Applicants: Chengdu BOE Optoelectronics Technology Co., Ltd., Chengdu, Sichuan (CN); BOE Technology Group Co., Ltd., Beijing (CN)

(72) Inventors: Yang YAO, Beijing (CN); Taoran ZHANG, Beijing (CN); Changchang LIU, Beijing (CN); Da ZHOU, Beijing (CN); Zailong MO, Beijing (CN)

(21) Appl. No.: 17/795,556

(22) PCT Filed: Sep. 30, 2021
(86) PCT No.: PCT/CN2021/122157

§ 371 Date: Jul. 27, 2022

(51) Int. Cl. H10K 59/80; H10K 59/12; H10K 59/35; H10K 71/10; H10K 102/00

(52) U.S. Cl. CPC H10K 59/8731; H10K 59/1201; H10K 59/35; H10K 59/879; H10K 71/10; H10K 2102/351

(57) ABSTRACT

A display substrate, a display apparatus, and a preparation method therefor are disclosed. The display substrate includes a light emitting element arranged on a base substrate, and an encapsulation structure layer arranged on a side of the light emitting element away from the base substrate; the encapsulation structure layer includes a first inorganic structure layer, an organic layer and a second inorganic structure layer sequentially stacked in a direction away from the base substrate; a refractive index of the first inorganic structure layer decreases gradually in the direction away from the base substrate, or first increases gradually and then decreases gradually in the direction away from the base substrate; the refractive index of the first inorganic structure layer varies from 1.51 to 1.74, and a refractive index of the second inorganic structure layer is greater than 1.74; and a thickness of the first inorganic structure layer is 0.99 μm to 1.21 μm.

### CROSS-REFERENCE TO RELATED APPLICATION

This application claims priority is a U.S. National Phase Entry of International Application PCT/CN2021/122157 having an international filing date of Sep. 30, 2021, and the contents disclosed in the above-mentioned application are hereby incorporated as a part of this application.

### TECHNICAL FIELD

Embodiments of the present disclosure relate to, but are not limited to, the field of display technology, in particular to a display substrate, a display apparatus, and a method for preparing a display substrate.

### BACKGROUND

Active Matrix Organic Light Emitting Diodes (AMOLED) are widely used in terminal display products with high-resolution color screens due to their advantages of self-luminescence, high contrast, wide viewing angle, high color gamut, high response speed, low power consumption, etc. However, some AMOLED display modules have problems of reddening on the periphery and color shift, which affect display effects.

### SUMMARY

The following is a summary of subject matters described herein in detail. The summary is not intended to limit the protection scope of the claims.

An embodiment of the present disclosure provides a display substrate, including a drive circuit layer, a light emitting structure layer and an encapsulation structure layer which are sequentially stacked on a base substrate, wherein the drive circuit layer includes a pixel drive circuit, the light emitting structure layer includes a light emitting element connected to the pixel drive circuit, the light emitting element includes an anode, an organic functional layer and a cathode which are sequentially stacked in a direction away from the base substrate; the encapsulation structure layer includes a first inorganic structure layer, an organic layer and a second inorganic structure layer which are sequentially stacked in the direction away from the base substrate; a refractive index of the first inorganic structure layer decreases gradually in the direction away from the base substrate, or the refractive index of the first inorganic structure layer first increases gradually and then decreases gradually in the direction away from the base substrate; the refractive index of the first inorganic structure layer varies from 1.51 to 1.74, and a refractive index of the second inorganic structure layer is greater than 1.74; and a thickness of the first inorganic structure layer is 0.99 μm to 1.21 μm.

An embodiment of the present disclosure further provides a display apparatus, including the display substrate described above.

An embodiment of the present disclosure further provides a method for preparing a display substrate, including:
forming a drive circuit layer on a base substrate, the drive circuit layer including a pixel drive circuit;
forming a light emitting structure layer on a side of the drive circuit layer facing away from the base substrate, wherein the light emitting structure layer includes a light emitting element connected to the pixel drive circuit, and the light emitting element includes an anode, an organic functional layer and a cathode which are sequentially stacked in a direction away from the base substrate; and
forming an encapsulation structure layer on a side of the light emitting structure layer facing away from the base substrate, wherein the encapsulation structure layer includes a first inorganic structure layer, an organic layer and a second inorganic structure layer which are sequentially stacked in the direction away from the base substrate; a refractive index of the first inorganic structure layer decreases gradually in the direction away from the base substrate, or the refractive index of the first inorganic structure layer first increases gradually and then decreases gradually in the direction away from the base substrate; the refractive index of the first inorganic structure layer varies from 1.51 to 1.74, and a refractive index of the second inorganic structure layer is greater than 1.74; and a thickness of the first inorganic structure layer is 0.99 μm to 1.21 μm.

Other aspects will become apparent upon reading and understanding the drawings and detailed description.

### BRIEF DESCRIPTION OF DRAWINGS

Accompanying drawings are used to provide further understanding for technical solutions of the present disclosure, constitute a part of the specification, and are used to explain the technical solutions of the present disclosure together with embodiments of the present disclosure, thus do not constitute a limitation on the technical solutions of the present disclosure. Shapes and sizes of the components in the accompanying drawings do not reflect actual scales and are only intended to illustrate the contents of the present disclosure.

FIG. 1 is a schematic diagram of a film layer structure of a display substrate according to some exemplary embodiments.

FIG. 2 is a schematic diagram of a sectional structure of the display substrate in FIG. 1 according to some exemplary embodiments.

FIG. 3 is a variation curve of transmittance of first inorganic layers with different thicknesses for light of different wavelengths in some techniques.

FIG. 4a is a schematic diagram of optical paths of red light and green light when passing through an encapsulation structure layer in a display substrate in some techniques.

FIG. 4b is a schematic diagram of optical paths of red light and green light when passing through an encapsulation structure layer in a display substrate in some exemplary embodiments.

FIG. 5a is an attenuation variation diagram of viewing angle-dependent brightness of five capping layers with different thicknesses for red light.

FIG. 5b is an attenuation variation diagram of viewing angle-dependent brightness of the capping layer, when having a thickness of 800 Å, for red light, green light and blue light.

FIG. 5c is an attenuation variation diagram of viewing angle-dependent brightness of the capping layer, when having a thickness of 900 Å, for red light, green light and blue light.

FIG. 6 is a curve of variation of JNCD with viewing angle under conditions of five different thicknesses of a capping layer.

FIG. 7 is a schematic diagram of a planar structure of a display substrate according to some exemplary embodiments.

### DETAILED DESCRIPTION

Those of ordinary skills in the art should understand that modifications or equivalent replacements may be made to the technical solutions of the embodiments of the present disclosure without departing from the spirit and scope of the technical solutions of the embodiments of the present disclosure, and they should all fall within the scope of the claims of the present disclosure.

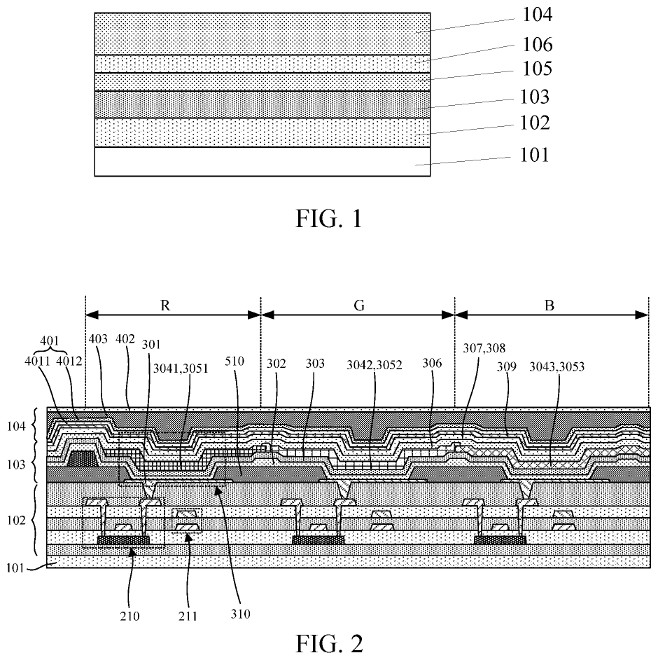

An embodiment of the present disclosure provides a display substrate. In some exemplary embodiments, as shown in FIG. 1 and FIG. 2, FIG. 1 is a schematic diagram of a film layer structure of a display substrate according to some exemplary embodiments, and FIG. 2 is a schematic diagram of a sectional structure of the display substrate in FIG. 1 according to some exemplary embodiments. The display substrate includes a drive circuit layer 102, a light emitting structure layer 103 and an encapsulation structure layer 104 which are sequentially stacked on a base substrate 101. The drive circuit layer 102 includes a pixel drive circuit, the light emitting structure layer 103 includes a light emitting element 310 connected to the pixel drive circuit, and the light emitting element 310 includes an anode 301, an organic functional layer and a cathode 309 which are sequentially stacked in a direction away from the base substrate 101. The encapsulation structure layer 104 includes a first inorganic structure layer 401, an organic layer 403 and a second inorganic structure layer 402 which are sequentially stacked in the direction away from the base substrate 101. A refractive index of the first inorganic structure layer 401 decreases gradually in the direction away from the base substrate 101, or the refractive index of the first inorganic structure layer 401 first increases gradually and then decreases gradually in the direction away from the base substrate 101. The refractive index of the first inorganic structure layer 401 varies from 1.51 to 1.74, and a refractive index of the second inorganic structure layer 402 is greater than 1.74. A thickness of the first inorganic structure layer 401 is 0.99 μm to 1.21 μm.

In the display substrate according to the embodiment of the present disclosure, the refractive index of the first inorganic structure layer 401 is set to decrease gradually in the direction away from the base substrate 101, or first increase gradually and then decrease gradually in the direction away from the base substrate 101, the refractive index of the first inorganic structure layer 401 is set to vary from 1.51 to 1.74, and the refractive index of the second inorganic structure layer 402 is set to be greater than 1.74. In this way, on the one hand, it is beneficial to improving a light emitting efficiency and brightness at a front viewing angle of the display substrate; and on the other hand, by setting the thickness of the first inorganic structure layer 401 to 0.99 μm to 1.21 μm, it is beneficial to shifting an emitting direction of green light emitted from green sub-pixels of the display substrate towards a front view direction, thereby improving the phenomenon of reddening on the periphery of the display substrate at the front viewing angle, and improving display effects.

In some exemplary embodiments, as shown in FIG. 2, the first inorganic structure layer 401 includes a first sub-inorganic layer 4011 and a second sub-inorganic layer 4012 which are sequentially stacked in a direction away from the base substrate 101, a refractive index of the first sub-inorganic layer 4011 may be 1.68 to 1.74, and a refractive index of the second sub-inorganic layer 4012 may be 1.57 to 1.68. As an example, a material of the first inorganic structure layer 401 may be silicon oxynitride, and the refractive indices of the first sub-inorganic layer 4011 and the second sub-inorganic layer 4012 may be adjusted by adjusting a ratio of nitrogen to oxygen in silicon oxynitride forming the first sub-inorganic layer 4011 and the second sub-inorganic layer 4012.

In some exemplary embodiments, as shown in FIG. 2, the material of the first inorganic structure layer 401 may be silicon oxynitride, a thickness of the first sub-inorganic layer 4011 may be 0.8 μm to 1.15 μm, and a thickness of the second sub-inorganic layer 4012 may be 0.06 μm to 0.19 μm. In an example of this embodiment, the thickness of the first sub-inorganic layer 4011 is 1 μm, and the thickness of the second sub-inorganic layer 4012 is 0.1 μm. In this way, transmittance of green light may be increased, the phenomenon of reddening on the periphery of the display substrate at the front viewing angle may be improved, and the display effects may be improved.

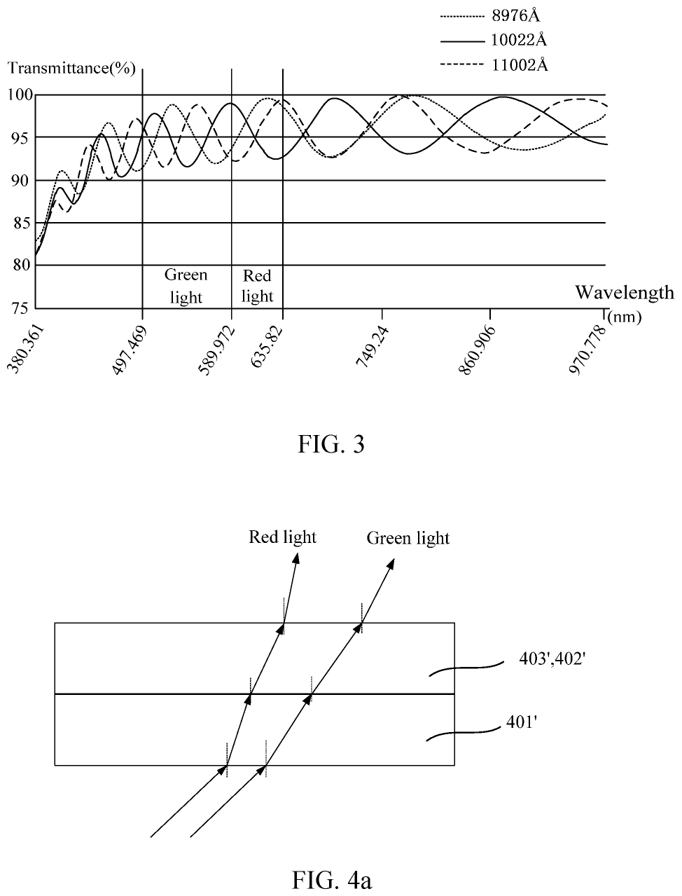

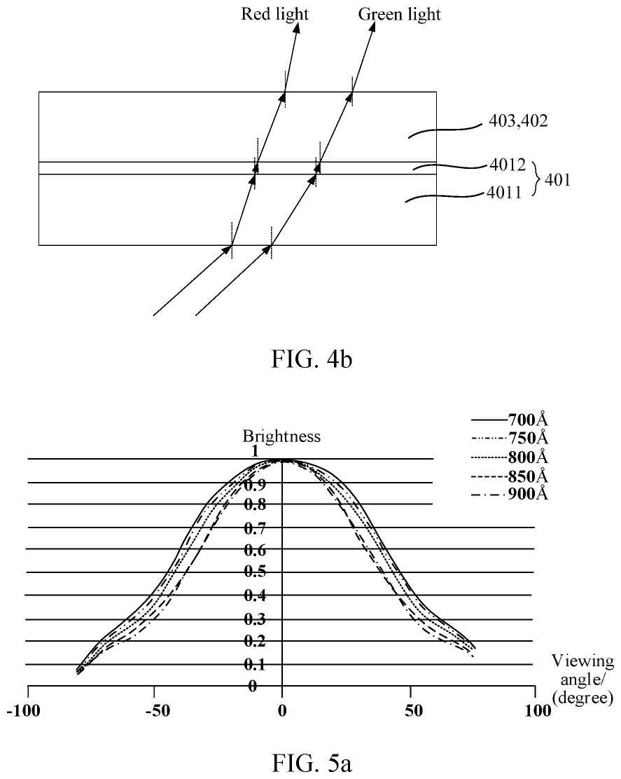

In some techniques, the encapsulation structure layer of the display substrate includes a first inorganic layer, an organic layer and a second inorganic layer which are stacked sequentially in a direction away from the base substrate, wherein the thickness of the first inorganic layer is about 1 μm (10000 Å), and after a middle of a display module is corrected to white by Gamma, there is a phenomenon of reddening on the periphery at a front viewing angle. The inventor of the present disclosure has found by study that the first inorganic layer of the encapsulation structure layer is equivalent to a microcavity, which reflects, refracts and absorbs light, and the first inorganic layer with the thickness of 1 μm has a transmittance of 92% for green light and a transmittance of 95% for red light. Therefore, in order to improve the phenomenon of reddening on the periphery of the display module at the front viewing angle, it is considered to increase the transmittance of the first inorganic layer for green light. By verifying the influence of the first inorganic layers with different thicknesses on the transmittance for light of different wavelengths, it is found that the transmittance of the first inorganic layer for light of different wavelengths varies periodically with an increase of the wavelengths, and the first inorganic layers with different thicknesses have different periodic variations in the transmittance for light of different wavelengths. As shown in FIG. 3, FIG. 3 is a variation curve of transmittance of first inorganic layers with different thicknesses (8976 Å, 10022 Å, 11002 Å) for light of different wavelengths in some techniques, wherein the abscissas represent wavelengths, with the unit of nanometer (nm), and the ordinates represent light transmittance. According to a verification result in FIG. 3, it is considered to increase the thickness of the first inorganic layer by 0.1 μm, so that the thickness of the first inorganic layer is 1.1 μm, the transmittance for green light is increased to 95%, and the transmittance for red light is still 95%, so as to improve the phenomenon of reddening on the periphery of the display substrate at the front viewing angle. Considering process errors, it is determined that the thickness of the first inorganic layer is designed to be 0.99 μm to 1.21 μm, i.e., the thickness of the first inorganic structure layer 401 in the embodiment of the present disclosure is set to 0.99 μm to 1.21 μm. In addition, it has also been found by the inventor of the present disclosure that, at a peripheral edge position of the display module, after red light and green light are emitted through the first inorganic layer 401′, the organic layer 403′ and the second inorganic layer 402′ of the encapsulation structure layer sequentially, the emitting direction of the red light and the emitting direction of the green light are both deviated from the front view direction, as shown in FIG. 4a. FIG. 4a is a schematic diagram of optical paths of red light and green light when passing through an encapsulation structure layer in a display substrate in some techniques. In order to improve the phenomenon of reddening on the periphery of the display module at the front viewing angle, it is considered to adjust the refractive index of the first inorganic layer 401′ to shift the emitting direction of the green light towards the front view direction, to increase a proportion of green light emission at the peripheral edge position of the display module. After the influence of the two factors, i.e., thickness and refractive index of the first inorganic layer 401′ is taken into consideration, in an embodiment of the present disclosure, the thickness of the first inorganic structure layer 401 of the encapsulation structure layer 104 is set to 0.99 μm to 1.21 μm, and the refractive index of the first inorganic structure layer 401 is set to decrease gradually in the direction away from the base substrate 101, or first increase gradually and then decrease gradually in the direction away from the base substrate 101, and the refractive index of the first inorganic structure layer 401 is set to vary from 1.51 to 1.74, so that the transmittance of green light through the encapsulation structure layer 104 may be increased, and the emitting direction of the green light may be shifted towards the front view direction (as shown in FIG. 4b, FIG. 4b is a schematic diagram of optical paths of red light and green light when passing through an encapsulation structure layer in a display substrate in some exemplary embodiments), thus increasing the proportion of green light emission at the peripheral edge position of the display module, thereby improving the phenomenon of reddening on the periphery of the display module at the front viewing angle and improving the display effects.

In some exemplary embodiments, the first inorganic structure layer 401 may further include a third sub-inorganic layer arranged on a side of the first sub-inorganic layer 4011 facing the base substrate 101, wherein a refractive index of the third sub-inorganic layer may be 1.51 to 1.72. Thus, the refractive index of the first inorganic structure layer 401 in this embodiment increases first and then decreases in the direction away from the base substrate 101, which is beneficial to improving the light emitting efficiency and brightness at the front viewing angle of the display substrate. In an embodiment of the present disclosure, the number of film layers of the first inorganic structure layer 401 may not be limited, and in other implementations, the number of the film layers of the first inorganic structure layer 401 may be three or more, and a thickness of a single film layer in the first inorganic structure layer 401 may be 0.05 μm.

In some exemplary embodiments, as shown in FIG. 2, a refractive index of the second inorganic structure layer 402 may be 1.74 to 1.88. As an example, the refractive index of the second inorganic structure layer 402 may be 1.82 to 1.84, e.g., 1.83; or the refractive index of the second inorganic structure layer 402 may gradually increase in the direction away from the base substrate 101.

In some exemplary embodiments, as shown in FIG. 2, the material of the second inorganic structure layer 402 may be silicon nitride, and a thickness of the second inorganic structure layer 402 may be 0.55 μm to 0.85 μm.

In some exemplary embodiments, as shown in FIG. 2, a thickness of the organic layer 403 may be 7.2 μm to 12.5 μm. The organic layer 403 may be prepared by an inkjet printing process. In the inkjet printing process, by adjusting a leveling speed of the material forming the organic layer 403, the quality of inkjet printing may be improved, thereby reducing the incidence of color-related defects such as color mixing. The refractive index of the organic layer 403 may be 1.1 to 1.3.

In some exemplary embodiments, as shown in FIG. 1 and FIG. 2, the display substrate may further include a capping layer (CPL) 105 arranged on a surface of the cathode 309 facing away from the base substrate 101, wherein a thickness of the capping layer 105 may be 700 Å to 1000 Å. As an example, the thickness of the capping layer 105 may be 729 Å to 891 Å, e.g., 810 Å. The encapsulation structure layer 104 is arranged on a side of the capping layer 105 facing away from the base substrate 101. In this embodiment, the thickness of the capping layer 105 is set to 729 Å to 891 Å, so that the phenomenon of color shift of the display substrate may be improved. The capping layer 105 may be made of an inorganic or an organic material, and the refractive index of the capping layer 105 may be 1.1 to 1.2.

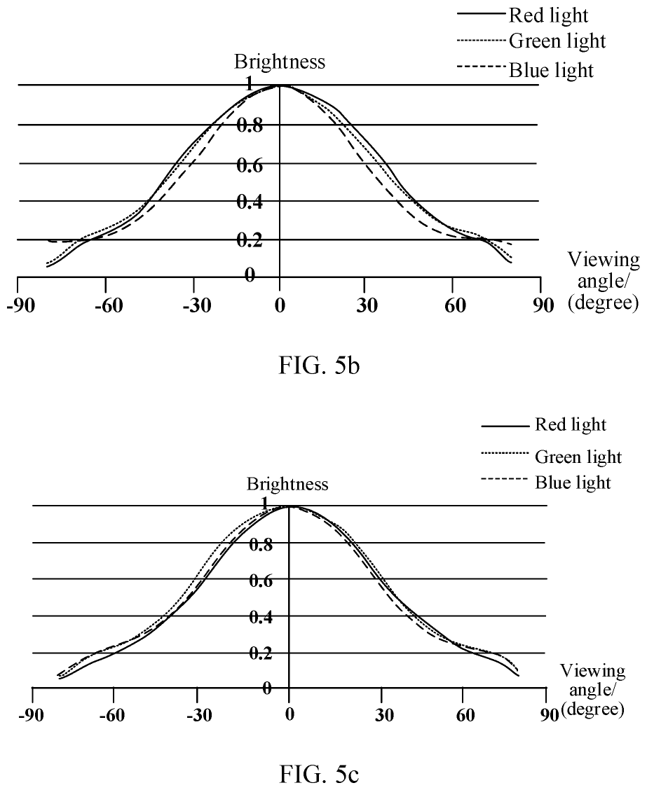

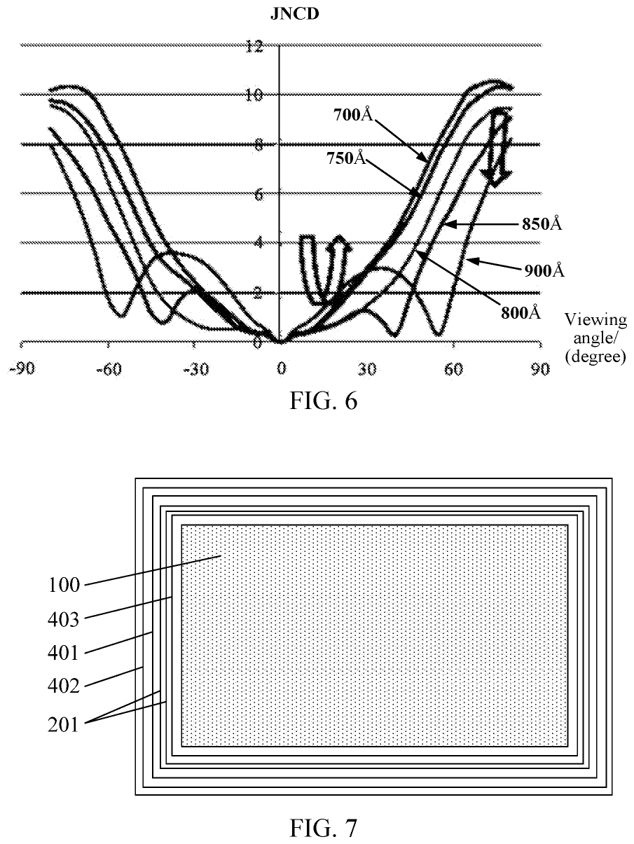

In order to improve the phenomenon of reddening on the periphery of the display substrate at the front viewing angle, the encapsulation structure layer 104 is configured so that the emitting direction of green light may be shifted towards the front view direction, then at a viewing angle deviating from the front view direction, the brightness of green light will be reduced, which may cause image reddening of the display substrate at a viewing angle deviating from the front view direction. The inventor of the present disclosure has verified attenuation conditions of viewing angle-dependent brightness of the capping layers 105 with different thicknesses for differently colored light, and found that the capping layers 105 with different thicknesses have different speeds of attenuation in viewing angle-dependent brightness for red light, and the capping layers 105 with a same thickness have different speeds of attenuation in viewing angle-dependent brightness for differently colored light. As shown in FIG. 5a, FIG. 5b and FIG. 5c, FIG. 5a is an attenuation variation diagram of viewing angle-dependent brightness of five capping layers 105 with different thicknesses for red light, FIG. 5b is an attenuation variation diagram of viewing angle-dependent brightness of the capping layer 105 with a thickness of 800 Å, for red light, green light and blue light, and FIG. 5c is an attenuation variation diagram of viewing angle-dependent brightness of the capping layer 105 with a thickness of 900 Å, for red light, green light and blue light. As shown in FIG. 5a, the attenuation conditions of viewing angle-dependent brightness for red light when the thickness of the capping layer 105 is 700 Å, 750 Å, 800 Å, 850 Å and 900 Å respectively are verified, and it can be seen that the capping layers 105 with different thicknesses have different speeds of attenuation in viewing angle-dependent brightness for red light, and the thicker the capping layer 105 is, the faster the brightness for red light attenuates. As shown in FIG. 5b, when the thickness of the capping layer 105 is 800 Å, the brightness for red light attenuates the slowest, followed by green light, the brightness for blue light attenuates the fastest, and the display substrate exhibits a pinkish image at a viewing angle deviating from the front view direction. As shown in FIG. 5c, when the thickness of the capping layer 105 is 900 Å, the brightness for green light attenuates the slowest, the brightness for red light and blue light attenuates slightly faster than the brightness for green light, and the display substrate exhibits a slightly cyan image at a viewing angle deviating from the front view direction. In addition, the inventor of the present disclosure has verified a condition of variation of a color offset value (JNCD) with viewing angle when the thickness of the capping layer 105 varies, as shown in FIG. 6. FIG. 6 is a curve of variation of JNCD with viewing angle under the condition of five different thicknesses of the capping layer 105, wherein the abscissa is a degree of viewing angle and the ordinate is a JNCD value. It can be seen that when the thickness of the capping layer 105 is 850 Å and 900 Å, the JNCD value increases unevenly and jumps with the change of viewing angle. When the thickness of the capping layer 105 is 700 Å, 750 Å and 800 Å, the JNCD value increases gradually with an increase of the viewing angle, wherein when the thickness of the capping layer 105 is 800 Å, the JNCD value changes most slowly and evenly with the increase of viewing angle. Based on the above verification results, in this embodiment, setting the thickness of the capping layer 105 to 729 Å to 891 Å may improve the phenomenon of color shift of the display substrate and improve the display effects.

In some exemplary embodiments, as shown in FIG. 1 and FIG. 2, the display substrate may further include a protective layer 106 arranged on a surface of the capping layer 105 facing away from the base substrate 101, and the encapsulation structure layer 104 is arranged on a surface of the protective layer 106 facing away from the base substrate 101. A material of the protective layer 106 may be LiF, a thickness of the protective layer 106 may be 500 Å to 700 Å. As an example, the thickness of the protective layer 106 may be 540 Å to 660 Å, e.g., 600 Å. The protective layer 106 may serve to protect the capping layer 105 and may also serve to absorb water. A refractive index of the protective layer 106 may be 1.1 to 1.3.

In some exemplary embodiments, as shown in FIG. 7, FIG. 7 is a schematic diagram of a planar structure of a display substrate according to some exemplary embodiments, the display substrate includes a display region 100 and a non-display region located on a periphery of the display region 100, wherein circumferential edges of the first inorganic structure layer 401, the organic layer 403 and the second inorganic structure layer 402 are all located in the non-display region. An orthographic projection of the second inorganic structure layer 402 on the base substrate 101 includes an orthographic projection of the first inorganic structure layer 401 on the base substrate 101, and the orthographic projection of the first inorganic structure layer 401 on the base substrate 101 includes an orthographic projection of the organic layer 403 on the base substrate 101. In this way, the encapsulation structure layer 104 may more effectively prevent external water and oxygen from intruding into the display substrate, thus protecting the light emitting element.

In an example of this embodiment, as shown in FIG. 7, the non-display region may include an isolation dam 201, and the isolation dam 201 is arranged on a side of the organic layer 403 away from the display region 100, wherein the circumferential edges of the first inorganic structure layer 401 and the second inorganic structure layer 402 are arranged on a side of the isolation dam 201 away from the display region 100. One or more isolation dams 201 may be arranged, and two isolation dams 201 are arranged in the example of FIG. 7. The organic layer 403 may be formed using an inkjet printing process, and the isolation dam 201 may block overflow of ink that forms the organic layer 403 during the formation of the organic layer 403. In some implementations, the isolation dam may be formed on a low voltage power supply line (VSS).

In an example of this embodiment, as shown in FIG. 7, the non-display region may include a gate drive circuit (GOA), and an orthographic projection of the organic layer 403 on the base substrate includes an orthographic projection of the gate drive circuit on the base substrate.

In some exemplary embodiments, as shown in FIG. 2, the display substrate includes a display region including a red sub-pixel R, a green sub-pixel G and a blue sub-pixel B, wherein each sub-pixel includes one light emitting element 310, and the light emitting element 310 which may be an organic light emitting diode (i.e., an OLED device). A total thickness of all film layers between the anode 301 and the cathode 309 in the OLED device of the red sub-pixel R may be 2484 Å to 2932 Å. A total thickness of all film layers between the anode 301 and the cathode 309 in the OLED device of the green sub-pixel G may be 2084 Å to 2462 Å. A total thickness of all film layers between the anode 301 and the cathode 309 in the OLED device of the blue sub-pixel B may be 1610 Å to 1917 Å.

In this embodiment, all film layers between the anode 301 and the cathode 309 in the OLED devices of the red sub-pixel, the green sub-pixel and the blue sub-pixel are set to have the above total thicknesses, so that when an optical microcavity structure is formed between the anode 301 and the cathode 309 of the OLED device, the light emission spectrum of the light emitting layer of the OLED device may be narrowed by microcavity effect, and the light emission intensity of light of a target wavelength may be enhanced, which is beneficial to improving color purity and intensity of light emission of the OLED device.

In some exemplary embodiments, as shown in FIG. 2, FIG. 2 illustrates three sub-pixels, which are respectively a red sub-pixel R, a green sub-pixel G and a blue sub-pixel B. Taking the red sub-pixel R as an example, the light emitting element (illustratively, an OLED device) 310 includes an anode 301, a light emitting layer 3051 and a cathode 309 which are sequentially stacked in the direction away from the base substrate 101, and the organic functional layer includes the light emitting layer 3051. Any one or more of the following film layers may be arranged between the anode 301 and the light emitting layer 3051: a hole injection layer 302, a hole transport layer 303 and an electron block layer 3041. Any one or more of the following film layers may be arranged between the light emitting layer 3051 and the cathode 309: a hole block layer 306, an electron transport layer 307 and an electron injection layer 308. Any one of the following film layers in the display region may be connected into an integral structure and cover the display region: a hole injection layer 302, a hole transport layer 303, a hole block layer 306, an electron transport layer 307, an electron injection layer 308 and a cathode 309. That is, the hole injection layers 302 of all sub-pixels in the display region may be connected into an integral structure and cover the display region, the hole injection layer 302 may be referred to as a common layer, and similarly, the hole transport layer 303, the hole block layer 306, the electron transport layer 307, the electron injection layer 308 and the cathode 309 may all be common layers. All the film layers located between the anode 301 and the cathode 309 in the light emitting element 310 may be referred to as organic functional layers.

In an example of this embodiment, as shown in FIG. 2, the light emitting element (e.g., an OLED device) 310 of each sub-pixel in the display region includes an anode 301, a hole injection layer 302, a hole transport layer 303, an electron block layer (3041 for the red sub-pixel R, 3042 for the green sub-pixel G, and 3043 for the blue sub-pixel B in the example of FIG. 2), a light emitting layer (3051 for the red sub-pixel R, 3052 for the green sub-pixel G, and 3053 for the blue sub-pixel B in the example of FIG. 2), a hole block layer 306, an electron transport layer 307, an electron injection layer 308 and a cathode 309 which are sequentially stacked in the direction away from the base substrate 101. The light emitting layer and the electron block layer of the OLED device of each sub-pixel in the display region may be unique to the sub-pixel and may not be shared with other sub-pixels. The light emitting layer and the electron block layer may be different for sub-pixels with different colors. In some implementations, a total thickness (microcavity length) of all film layers located between the anode 301 and the cathode 309 in the OLED device may be adjusted by adjusting a thickness of the unique film layer (e.g., the light emitting layer and the electron block layer) of the OLED device for the sub-pixel of each color, so as to satisfy a condition of microcavity interference.

As an example, a thickness of the hole injection layer 302 may be 90 Å to 110 Å. The hole injection layer 302 may be made of a p-type doped hole transport material, in which a doping ratio may be 1%, for example, a material formed by doping MoO₃ (molybdenum trioxide) in TAPC (4,4′-cyclohexylbis[N,N-bis(4-methylphenyl)aniline]), i.e., TAPC:MoO₃. The hole injection layer 302 serves to reduce hole injection barrier and improve a hole injection efficiency.

As an example, a thickness of the hole transport layer 303 may be 1060 Å to 1100 Å. A material of the hole transport layer 303 and a material of the electron block layer may each include a hole transport material containing a group such as aniline, aromatic amine, carbazole, fluorine, or spirofluorene, which for example may be 4,4′-bis[N-(1-naphthyl)-N-phenylamino]biphenyl (NPB), N,N′-bis(3-methylphenyl)-N,N′-diphenyl-[1,1′-biphenyl]-4,4′-diamine (TPD), 4-phenyl-4′-(9-phenylfluorene-9-yl)triphenylamine (BAFLP), 4,4′-bis[N-(9,9-dimethylfluoren-2-yl)-N-phenylamino]biphenyl (DFLDPBi), 4,4′-bis(9-carbazolyl)biphenyl (CBP), or 9-phenyl-3-[4-(10-phenyl-9-anthryl)phenyl]-9H-carbazole (PCzPA), etc. The hole transport layer 303 serves to improve hole transport rate, and may also reduce the hole injection barrier and improve the hole injection efficiency.

As an example, a thickness of the hole block layer 306 may be 45 Å to 55 Å. A material of the hole block layer 306 may include an electron transport material containing a group such as triazine, imine, carbazole, or nitrile, for example, bis(2-methyl-8-quinolinyl)-4-(phenylphenol)aluminum (BAlq). The hole block layer 306 may block holes and excitons in the light emitting layer from migrating to a side where the cathode 309 is located, thus improving the light emitting efficiency.

As an example, a thickness of the electron transport layer 307 may be 290 Å to 310 Å. The electron transport layer 307 may be a mixed film of an electron transport material and lithium octahydroxyquinoline (Liq), and the electron transport material may be a nitrogen-containing heterocyclic compound, such as 7-diphenyl-1,10-phenanthroline (Bphen), 1,3,5-tris(1-phenyl-1H-benzimidazol-2-yl)benzene (TPBi), etc. The electron transport layer 307 may increase an electron transport rate.

As an example, a thickness of the electron injection layer 308 may be 10 Å to 20 Å. A material of the electron injection layer 308 may be lithium fluoride (LiF), ytterbium (Yb), magnesium (Mg) or calcium (Ca). The electron injection layer 308 may reduce electron injection barrier and improve an electron injection efficiency.

As an example, a thickness of the light emitting layer 3051 in the OLED device of the red sub-pixel is d1, a thickness of the light emitting layer 3052 in the OLED device of the green sub-pixel is d2, and a thickness of the light emitting layer 3053 in the OLED device of the blue sub-pixel is d3, where d1>d2>d3. As an example, d1=450 Å, d2=360 Å, and d3=180 Å. In some implementations, the material of the light emitting layer in the OLED device of each sub-pixel may include a host material and a dopant material.

As an example, a thickness of the electron block layer 3041 in the OLED device of the red sub-pixel is D1, a thickness of the electron block layer 3042 in the OLED device of the green sub-pixel is D2, and a thickness of the electron block layer 3043 in the OLED device of the blue sub-pixel is D3, where D1>D2>D3. As an example, D1=720 Å, D2-360 Å, and D3=50 Å.

As an example, the anode 301 of the OLED device may be made of a material with a high work function. For a top-emission type OLED, the anode 301 may employ a composite film layer structure of a metal layer with a high reflectivity and a transparent oxide layer, e.g., Ag/ITO (silver/indium tin oxide), Ag/IZO (silver/indium zinc oxide), or ITO/Ag/ITO, etc. In this example, ITO/Ag/ITO is used for the anode 301, wherein the thicknesses of the three film layers may be 70 Å, 1000 Å and 70 Å sequentially.

As an example, a material of the cathode 309 of the OLED device may be magnesium (Mg), silver (Ag), or aluminum (Al), or an alloy material, such as an alloy of Mg:Ag. In this example, the material of the cathode 309 is an alloy of Mg:Ag, with a ratio of Mg to Ag being 9:1, and a thickness of the cathode 309 may be 120 Å to 140 Å. The cathode 309 may be formed by an evaporation process.

In this embodiment, parameters of part of the film layers of the display substrate may be as shown in Table 1.

TABLE 1

| | | Material of film | R | G | B |
|---|---|---|---|---|---|
| | Film layer | layer | Thickness | | |
| Encapsulation | Second inorganic | SiNₓ(n = 1.83) | 0.7 um | | |
| structure layer | structure layer | | | | |
| | Organic layer | / | 8 um | | |
| | Second | SioₓN_{y}(n = 1.63) | 0.1 um | | |
| | sub-inorganic layer | | | | |
| | First sub-inorganic | SiOₓN_{y}(n = 1.73) | 1 um | | |
| | layer | | | | |
| | Protective layer | LiF | 600 | | |
| | Capping layer | / | 810 | | |
| OLED device/film | Cathode | Mg:Ag (9:1) | 130 | | |
| layer thickness | Electron injection | Yb | 15 | | |
| unit (Å) | layer | | | | |
| | Electron transport | / | 300 | | |
| | layer | | | | |
| | Hole block layer | / | 50 | | |
| | Light emitting layer | host material + | 450 | 360 | 180 |
| | | dopant material | | | |
| | Electron block layer | / | 720 | 360 | 50 |

| | | |
|---|---|---|
| Hole transport layer | / | 1080 |
| Hole injection layer | / | 100 |
| Anode | ITO/Ag/ITO | 70/1000/70 |

Backplane circuit

In another example of this embodiment, ITO/Ag/ITO is used for the anode 301, wherein the thicknesses of the three film layers may be 86 Å, 1000 Å and 86 Å sequentially. The thickness of the hole transport layer 303 may be 1055 Å. d1=450 Å, d2=400 Å, and d3=180 Å. D1=730 Å, D2-360 Å, and D3=50 Å. Thicknesses of other film layers may be the same as those in the preceding embodiments. In this embodiment, parameters of part of the film layers of the display substrate may be as shown in Table 2.

TABLE 2

| | | | R | G | B |
|---|---|---|---|---|---|
| | Film layer | Material of film layer | Thickness | | |
| Encapsulation | Second inorganic | SiNₓ(n = 1.83) | 0.7 um | | |
| structure | structure layer | | | | |
| layer | Organic layer | / | 8 um | | |
| | Second | SioₓN_{y}(n = 1.63) | 0.1 um | | |
| | sub-inorganic layer | | | | |
| | First sub-inorganic | SiOₓN_{y}(n = 1.73) | 1 um | | |
| | layer | | | | |
| | Protective layer | LiF | 600 | | |
| | Capping layer | / | 810 | | |
| OLED | Cathode | Mg:Ag(9:1) | 130 | | |
| device/film | Electron injection | Yb | 15 | | |
| layer | layer | | | | |
| thickness unit | Electron transport | / | 300 | | |
| (Å) | layer | | | | |
| | Hole block layer | / | 50 | | |
| | Light emitting layer | Host material + dopant | 450 | 360 | 180 |
| | | material | | | |
| | Electron block layer | / | 720 | 360 | 50 |

| | | |
|---|---|---|
| Hole transport layer | / | 1055 |
| Hole injection layer | / | 100 |
| Anode | ITO/Ag/ITO | 86/1000/86 |

Backplane circuit

For the display substrates in the two embodiments of Table 1 and Table 2, the phenomenon of reddening on the periphery of the display substrate at the front viewing angle and the phenomenon of color shift in some techniques are improved, and no defects such as color mixing, dark lines, bright lines, dark spots and bright spots are produced.

In some exemplary embodiments, the base substrate 101 may be a flexible base substrate or may be a rigid base substrate. The flexible base substrate may include a first flexible material layer, a first inorganic material layer, an adhesive layer, a second flexible material layer and a second inorganic material layer which are stacked. Materials of the first flexible material layer and the second flexible material layer may be polyimide (PI), polyethylene terephthalate (PET) or surface treated polymer soft films. Materials of the first inorganic material layer and the second inorganic material layer may be silicon nitride (SiNx) or silicon oxide (SiOx), for improving the water and oxygen resistance of the base substrate, and a material of the adhesive layer may be amorphous silicon (a-si).

In some exemplary implementations, as shown in FIG. 2, the drive circuit layer 102 may include multiple transistors and a storage capacitor which form the pixel drive circuit. FIG. 2 illustrates an example in which each pixel drive circuit includes one drive transistor 210 and one storage capacitor 211. In some implementations, the drive circuit layer 102 may include: a first insulating layer arranged on the base substrate 101; an active layer arranged on the first insulating layer; a second insulating layer covering the active layer; a gate electrode and a first capacitor electrode arranged on the second insulating layer; a third insulating layer covering the gate electrode and the first capacitor electrode; a second capacitor electrode arranged on the third insulating layer; a fourth insulating layer covering the second capacitor electrode, via holes being formed on the second insulating layer, the third insulating layer, and the fourth insulating layer, with the via holes exposing the active layer; a source electrode and a drain electrode arranged on the fourth insulating layer, the source electrode and the drain electrode being respectively connected to the active layer through the respective via holes; and a planarization layer covering the foregoing structures, a via hole being formed on the planarization layer, with the via hole exposing the drain electrode. The active layer, the gate electrode, the source electrode and the drain electrode form the drive transistor 210, and the first capacitor electrode and the second capacitor electrode form the storage capacitor 211.

In some exemplary implementations, as shown in FIG. 2, the light emitting structure layer 103 may include an anode 301, a pixel definition layer 510, a cathode 309, and an organic functional layer between the anode 301 and the cathode 309. The organic functional layer at least includes a light emitting layer (3051 for the red sub-pixel, 3052 for the green sub-pixel and 3053 for the blue sub-pixel in the example in FIG. 2). The organic functional layer may further include the hole injection layer 302, the hole transport layer 303, the electron block layer (3041 for the red sub-pixel, 3042 for the green sub-pixel, and 3043 for the blue sub-pixel in the example in FIG. 2), the hole block layer 306, the electron transport layer 307 and the electron injection layer 308. The anode 301 is arranged on the planarization layer of the drive circuit layer 102, and is connected to the drain electrode of the drive transistor 210 through a via hole provided on the planarization layer. The pixel definition layer 510 is arranged on a side of the anode 301 facing away from the base substrate 101, the pixel definition layer 510 is provided with a pixel opening, the pixel definition layer 510 covers a portion of a surface of the anode 301 close to a circumferential edge, the pixel opening exposes the remaining portion of the surface of the anode 301, and multiple film layers of the organic functional layer and the cathode 309 are sequentially stacked on the portion of the surface of the anode 301 which is exposed by the pixel opening. The anode 301, the organic functional layer and the cathode 303 of each sub-pixel form an OLED device which is configured to emit light of a corresponding color under the drive of a corresponding pixel drive circuit. The light emitting structure layer 103 may further include other film layers, e.g., post spacers and the like provided on the pixel definition layer 510.

A method for preparing a display substrate in some exemplary embodiments is described below with reference to FIG. 2. In some exemplary implementations, a preparation process of the display substrate may include the following operations.

1) A drive circuit layer 102 is formed on a base substrate 101, the drive circuit layer 102 includes a pixel drive circuit. As an example, as shown in FIG. 2, a preparation process of the drive circuit layer 102 may include:
depositing a first insulating thin film and an active layer thin film sequentially on a base substrate 101, and pattering the active layer thin film by a patterning process to form a first insulating layer covering the base substrate 101 and a pattern of an active layer arranged on the first insulating layer, wherein the pattern of the active layer at least includes an active layer of each sub-pixel;
then, depositing a second insulating thin film and a first metal thin film sequentially, and pattering the first metal thin film by a patterning process to form a second insulating layer covering the pattern of the active layer and a pattern of a first gate metal layer arranged on the second insulating layer, wherein the pattern of the first gate metal layer at least includes a gate electrode and a first capacitor electrode of each sub-pixel;
then, depositing a third insulating thin film and a second metal thin film sequentially, and patterning the second metal thin film by a patterning process to form a third insulating layer covering the first gate metal layer and a pattern of a second gate metal layer arranged on the third insulating layer, wherein the pattern of the second gate metal layer at least includes a second capacitor electrode of each sub-pixel, and a position of the second capacitor electrode corresponds to that of the first capacitor electrode; and the first capacitor electrode and the second capacitor electrode constitute a storage capacitor 211;
then, depositing a fourth insulating thin film, and patterning the fourth insulating thin film by a patterning process to form a pattern of a fourth insulating layer covering the second gate metal layer, wherein the fourth insulating layer of each sub-pixel is provided with at least two via holes, the fourth insulating layer, the third insulating layer and the second insulating layer in the two via holes are etched away to expose a surface of the active layer of each sub-pixel;
then, depositing a third metal thin film, and patterning the third metal thin film by a patterning process to form a pattern of a source-drain metal layer on the fourth insulating layer, wherein the source-drain metal layer at least includes a source electrode and a drain electrode of each sub-pixel, and the source electrode and the drain electrode are respectively connected to the active layer through two via holes penetrating the fourth insulating layer, the third insulating layer and the second insulating layer; and
then, coating a planarization thin film of an organic material on the base substrate 101 on which the above patterns are formed, and forming a via hole on the planarization thin film of each sub-pixel through the processes such as masking, exposing and developing, wherein the planarization thin film in the via hole is developed away to expose a surface of the drain electrode, thereby forming a planarization layer (PLN) covering the base substrate 101.

At this point, the drive circuit layer 102 has been prepared on the base substrate 101, as shown in FIG. 2. In the drive circuit layer 102, the active layer, the gate electrode, the source electrode, and the drain electrode constitute the drive transistor 210 of the pixel drive circuit, and the first capacitor electrode and the second capacitor electrode constitute the storage capacitor 211 of the pixel drive circuit. The pixel drive circuit may drive the OLED device of each sub-pixel in an active matrix drive mode.

In this example, the first insulating layer, the second insulating layer, the third insulating layer, and the fourth insulating layer may be made of any one or more of silicon oxide (SiOx), silicon nitride (SiNx), and silicon oxynitride (SiON), and may be in a single layer, multiple layers, or a composite layer. The first insulating layer may be called a buffer layer, which is used for improving the water and oxygen resistance of the base substrate 101. The second insulating layer and the third insulating layer may be called gate insulating (GI) layers. The fourth insulating layer may be called an interlayer dielectric (ILD) layer. The first metal thin film, the second metal thin film and the third metal thin film may be made of metal materials, such as any one or more of silver (Ag), copper (Cu), aluminum (Al), titanium (Ti) and molybdenum (Mo), or alloy materials of the aforementioned metals, such as aluminum neodymium alloy (AlNd) or molybdenum niobium alloy (MoNb), and may be in a single-layered structure or a multilayered composite structure, such as Ti/Al/Ti, etc. The active layer thin film may be made of amorphous indium gallium zinc oxide (a-IGZO), zinc oxynitride (ZnON), indium zinc tin oxide (IZTO), amorphous silicon (a-Si), polysilicon (p-Si), hexathiophene, polythiophene, etc.

2) An anode layer is formed on a side of the drive circuit layer 102 away from the base substrate 101, the anode layer includes multiple anodes 301. As an example, an anode thin film is deposited on the base substrate 101 on which the above patterns are formed, and the anode thin film is patterned by a patterning process to form an anode layer including multiple anodes 301. The anode 301 is formed on the planarization layer of the drive circuit layer 102 and is connected to the drain electrode of the drive transistor 210 through a via hole on the planarization layer.

3) A pixel definition layer 510 is formed. A pixel definition thin film is coated on the base substrate 101 on which the above patterns are formed, and a pixel definition layer 510 having a pixel opening is formed by masking, exposing, developing, etc., wherein the pixel definition thin film in the pixel opening is developed away to expose a surface of a corresponding anode 301, and the pixel definition layer 510 covers a portion of the surface of the anode 301 close to the circumferential edge. A material of the pixel definition layer 510 may be polyimide, acrylic, polyethylene terephthalate, or the like. Subsequently, post spacers (PS) may be formed on the pixel definition layer 510.

4) An organic functional layer and a cathode 309 are formed on a surface of the anode 301 facing away from the base substrate 101. A hole injection layer 302, a hole transport layer 303, an electron block layer (3041 for the red sub-pixel, 3042 for the green sub-pixel, and 3043 for the blue sub-pixel), a light emitting layer (3051 for the red sub-pixel, 3052 for the green sub-pixel, and 3053 for the blue sub-pixel), a hole block layer 306, an electron transport layer 307, an electron injection layer 308 and a cathode 309 are sequentially formed on the surface of the anode 301 facing away from the base substrate 101. All film layers in this step may be formed by an evaporation process. At this point, the preparation of the light emitting structure layer 103 has been completed.

5) A capping layer 105 and a protective layer 106 are sequentially formed on a surface of the light emitting structure layer 103 facing away from the base substrate 101.

6) An encapsulation structure layer 104 is formed on a surface of the protective layer 106 facing away from the base substrate 101. As an example, a first sub-inorganic layer 4011 and a second sub-inorganic layer 4012 of a first inorganic structure layer 401, an organic layer 403 and a second inorganic structure layer 402 are sequentially formed on the surface of the protective layer 106 facing away from the base substrate 101. The first inorganic structure layer 401 and the second inorganic structure layer 402 may both be formed by a chemical vapor deposition method, and the organic layer 403 may be formed by an inkjet printing process. The encapsulation structure layer 104 may effectively prevent water and oxygen from intruding into the light emitting structure layer 103, thus protecting the light emitting element 310.

Based on the above content, an embodiment of the present disclosure further provides a method for preparing a display substrate, including:
forming a drive circuit layer on a base substrate, wherein the drive circuit layer includes a pixel drive circuit;
forming a light emitting structure layer on a side of the drive circuit layer facing away from the base substrate, wherein the light emitting structure layer includes a light emitting element connected to the pixel drive circuit, and the light emitting element includes an anode, an organic functional layer and a cathode which are sequentially stacked in a direction away from the base substrate; and
forming an encapsulation structure layer on a side of the light emitting structure layer facing away from the base substrate, wherein the encapsulation structure layer includes a first inorganic structure layer, an organic layer and a second inorganic structure layer which are sequentially stacked in the direction away from the base substrate; a refractive index of the first inorganic structure layer decreases gradually in the direction away from the base substrate, or the refractive index of the first inorganic structure layer first increases gradually and then decreases gradually in the direction away from the base substrate; the refractive index of the first inorganic structure layer varies from 1.51 to 1.74, and a refractive index of the second inorganic structure layer is greater than 1.74; and a thickness of the first inorganic structure layer is 0.99 μm to 1.21 μm.

An embodiment of the present disclosure further provides a display apparatus, including the display substrate described in any of the aforementioned embodiments. The display apparatus may be any product or component with a display function, such as a mobile phone, a tablet computer, a television, a display, a notebook computer, a digital photo frame, or a navigator.

In the accompanying drawings, a size of a constituent element, and a thickness of a layer or an area are sometimes exaggerated for clarity. Therefore, implementations of the present disclosure are not necessarily limited to the size, and the shape and size of each part in the accompanying drawings do not reflect actual scales. In addition, the accompanying drawings schematically show some examples, and the implementations of the present disclosure are not limited to the shapes or numerical values shown in the accompanying drawings.

In the description herein, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the description herein, orientation or positional relations indicated by the terms “up”, “down”, “left”, “right”, “top”, “inside”, “outside”, “axial direction”, “four corners” and the like are based on the orientation or positional relations shown in the drawings, which are merely simplified description for facilitating describing the embodiments of the present disclosure, rather than indicating or implying that the structures referred to have a specific orientation, or are constructed and operated in a particular orientation, and therefore they should not be construed as limitations on the present disclosure.

In the description herein, unless explicitly specified and defined otherwise, the terms “connection”, “fixed connection”, “installation” and “assembly” are to be understood broadly, which, for example, may be a fixed connection, or a detachable connection, or an integral connection. The terms “installation”, “connection” and “fixed connection” may refer to a direct connection, or an indirect connection through an intermediate medium, or may be an internal connection between two elements. Those of ordinary skills in the art may understand the meanings of the above terms in the embodiments of the present disclosure according to the situation.

1. A display substrate, comprising a drive circuit layer, a light emitting structure layer and an encapsulation structure layer which are sequentially stacked on a base substrate, wherein the drive circuit layer comprises a pixel drive circuit, the light emitting structure layer comprises a light emitting element connected to the pixel drive circuit, the light emitting element comprises an anode, an organic functional layer and a cathode which are sequentially stacked in a direction away from the base substrate;
the encapsulation structure layer comprises a first inorganic structure layer, an organic layer and a second inorganic structure layer which are sequentially stacked in the direction away from the base substrate; a refractive index of the first inorganic structure layer decreases gradually in the direction away from the base substrate, or the refractive index of the first inorganic structure layer first increases gradually and then decreases gradually in the direction away from the base substrate; the refractive index of the first inorganic structure layer varies from 1.51 to 1.74, and a refractive index of the second inorganic structure layer is greater than 1.74; and a thickness of the first inorganic structure layer is 0.99 μm to 1.21 μm.

2. The display substrate according to claim 1, wherein the first inorganic structure layer comprises a first sub-inorganic layer and a second sub-inorganic layer which are sequentially stacked in the direction away from the base substrate, a refractive index of the first sub-inorganic layer is 1.68 to 1.74, and a refractive index of the second sub-inorganic layer is 1.57 to 1.68.

3. The display substrate according to claim 2, wherein a material of the first inorganic structure layer is silicon oxynitride, and a thickness of the first sub-inorganic layer is 0.8 μm to 1.15 μm, and a thickness of the second sub-inorganic layer is 0.06 μm to 0.19 μm.

4. The display substrate according to claim 2, wherein the first inorganic structure layer further comprises a third sub-inorganic layer arranged on a side of the first sub-inorganic layer facing the base substrate, and a refractive index of the third sub-inorganic layer is 1.51 to 1.72.

5. The display substrate according to claim 1, wherein the refractive index of the second inorganic structure layer is 1.74 to 1.88.

6. The display substrate according to claim 5, wherein a material of the second inorganic structure layer is silicon nitride, and a thickness of the second inorganic structure layer is 0.55 μm to 0.85 μm.

7. The display substrate according to claim 5, wherein the refractive index of the second inorganic structure layer is 1.82 to 1.84, or the refractive index of the second inorganic structure layer increases gradually in the direction away from the base substrate.

8. The display substrate according to claim 1, wherein a thickness of the organic layer is 7.2 μm to 12.5 μm.

9. The display substrate according to claim 1, further comprising a capping layer arranged on a surface of the cathode facing away from the base substrate, wherein a thickness of the capping layer is 700 Å to 1000 Å, and the encapsulation structure layer is arranged on a side of the capping layer facing away from the base substrate.

10. The display substrate according to claim 9, further comprising a protective layer arranged on a surface of the capping layer facing away from the base substrate, wherein the encapsulation structure layer is arranged on a surface of the protective layer facing away from the base substrate; a material of the protective layer is LiF, and a thickness of the protective layer is 500 Å to 700 Å

11. The display substrate according to claim 1, comprising a display region, wherein the display region comprises a red sub-pixel, a green sub-pixel and a blue sub-pixel, the light emitting element is an organic light emitting diode;
a total thickness of all film layers between an anode and a cathode in a light emitting element of the red sub-pixel is 2484 Å to 2932 Å;
a total thickness of all film layers between an anode and a cathode in a light emitting element of the green sub-pixel is 2084 Å to 2462 Å; and
a total thickness of all film layers between an anode and a cathode in a light emitting element of the blue sub-pixel is 1610 Å to 1917 Å.

12. The display substrate according to claim 11, wherein the organic functional layer comprises a light emitting layer; any one or more of the following film layers are further arranged between the anode and the light emitting layer: a hole injection layer, a hole transport layer and an electron block layer; any one or more of the following film layers are further arranged between the light emitting layer and the cathode: a hole block layer, an electron transport layer and an electron injection layer; and
any one of the following film layers in the display region is connected into an integral structure and covers the display region: a hole injection layer, a hole transport layer, a hole block layer, an electron transport layer, an electron injection layer and a cathode.

13. The display substrate according to claim 12, wherein a thickness of the light emitting layer in the light emitting element of the red sub-pixel is d1, a thickness of the light emitting layer in the light emitting element of the green sub-pixel is d2, and a thickness of the light emitting layer in the light emitting element of the blue sub-pixel is d3, where d1>d2>d3.

14. The display substrate according to claim 12, wherein a thickness of the electron block layer in the light emitting element of the red sub-pixel is D1, a thickness of the electron block layer in the light emitting element of the green sub-pixel is D2, and a thickness of the electron block layer in the light emitting element of the blue sub-pixel is D3, where D1>D2>D3.

15. The display substrate according to claim 1, comprising a display region and a non-display region located on a periphery of the display region, wherein circumferential edges of the first inorganic structure layer, the organic layer and the second inorganic structure layer are all located in the non-display region;
an orthographic projection of the second inorganic structure layer on the base substrate comprises an orthographic projection of the first inorganic structure layer on the base substrate, and the orthographic projection of the first inorganic structure layer on the base substrate comprises an orthographic projection of the organic layer on the base substrate.

16. The display substrate according to claim 15, wherein the non-display region comprises an isolation dam, the isolation dam is arranged on a side of the organic layer away from the display region, and the circumferential edges of the first inorganic structure layer and the second inorganic structure layer are arranged on a side of the isolation dam away from the display region.

17. The display substrate according to claim 15, wherein the non-display region comprises a gate drive circuit, and the orthographic projection of the organic layer on the base substrate comprises an orthographic projection of the gate drive circuit on the base substrate.

18. A display apparatus, comprising the display substrate according to claim 1.

19. A method for preparing a display substrate, comprising:
forming a drive circuit layer on a base substrate, the drive circuit layer comprising a pixel drive circuit;
forming a light emitting structure layer on a side of the drive circuit layer facing away from the base substrate, wherein the light emitting structure layer comprises a light emitting element connected to the pixel drive circuit, and the light emitting element comprises an anode, an organic functional layer and a cathode which are sequentially stacked in a direction away from the base substrate; and
forming an encapsulation structure layer on a side of the light emitting structure layer facing away from the base substrate, wherein the encapsulation structure layer comprises a first inorganic structure layer, an organic layer and a second inorganic structure layer which are sequentially stacked in the direction away from the base substrate; a refractive index of the first inorganic structure layer decreases gradually in the direction away from the base substrate, or the refractive index of the first inorganic structure layer first increases gradually and then decreases gradually in the direction away from the base substrate; the refractive index of the first inorganic structure layer varies from 1.51 to 1.74, and a refractive index of the second inorganic structure layer is greater than 1.74; and a thickness of the first inorganic structure layer is 0.99 μm to 1.21 μm.

20. The method for preparing a display substrate according to claim 19, wherein in a process of forming the encapsulation structure layer, the first inorganic structure layer and the second inorganic structure layer are each formed by a chemical vapor deposition method.
